(19) United States
(12) Patent Application Publication
(10) Pub. No.: US 2006/0148219 A1
(43) Pub. Date: Jul. 6, 2006

(54) Method for photomask processing

(75) Inventor: Hong-Lae Kim, Icheon-city (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Kangnam-ku (KR)

(21) Appl. No.: 11/320,589

(22) Filed: Dec. 30, 2005

(30) Foreign Application Priority Data
Dec. 31, 2004 (KR) 10-2004-0118438

(51) Int. Cl. H01L 21/04

(52) U.S. Cl. 438/510

(57) ABSTRACT

A method for photomask processing including the formation of a photoresist pattern for a P-Well. The method further includes implanting ions for the P-well using the photoresist pattern as an ion implantation mask, coating another photoresist for the N-well that has a higher etch resistance than that of the photoresist for the P-well, removing the photoresist for the P-well, implanting ions for the N-well, and removing the photoresist. The method reduces the number of photomask processes for ion implantation, so the total processing cost can be reduced.

### CROSS-REFERENCE TO RELATED APPLICATION

This application claims priority to and the benefit of Korean Patent Application No. 10-2004-0118438 filed in the Korean Intellectual Property Office on Dec. 31, 2004, the entire contents of which are incorporated herein by reference.

### BACKGROUND OF THE INVENTION

(a) Field of the Invention

The present invention relates to a method for photomask processing. More particularly, the present invention relates to a method for photomask processing that can reduce photomask steps for ion implantation processes.

(b) Description of the Related Art

Since personal computers were developed, semiconductor devices have been widely used in various applications, and as processing technologies and circuit technologies have been improved, devices having higher integration have been developed. Manufacturing of semiconductor devices includes various required manufacturing processes, from manufacturing silicon wafers to packaging integrated circuits.

Among the semiconductor manufacturing processes, a photomask process wherein a photoresist is patterned has become important.

A typical photomask process will be described hereinafter.

Firstly, after preparing a wafer by cleaning a surface thereof, alignment marks are formed on the wafer. Subsequently, a photoresist film is coated on the wafer, and a soft-bake process wherein solvent of the photoresist is evaporated follows in order to enhance adhesion of the photoresist. Then, an alignment process for aligning a photomask to the wafer and an exposure process for exposing the photoresist layer of the wafer using the photomask are performed.

Next, a hard-bake process is performed to enhance adhesion of the photoresist on the wafer, and the exposed photoresist layer is removed in a development process.

FIG. 1A to FIG. 1B are cross-sectional views showing principal stages of a conventional photomask process.

Firstly, as shown in FIG. 1A, a photoresist is coated on a semiconductor substrate 110. In a P-well photomask process, the photoresist is exposed by using a P-Well photomask 100 and is developed to a predetermined pattern 120. After an ion implantation process 130, the photoresist is removed. Consequently, P-well regions 140 are formed.

Next, as shown in FIG. 1B, a photoresist is coated on the semiconductor substrate 110 provided with the P-well regions 140. In an N-well photomask process, the photoresist is exposed by using an N-Well photomask 150 and is developed to a predetermined pattern 160. After an ion implantation process 170, the photoresist is removed. Consequently, N-wells 180 are formed.

In the above embodiment of a semiconductor process, two photomask processes are required, so cost and time for processing may be increased.

The above information disclosed in this Background section is only for enhancement of understanding of the background of the invention and therefore it may contain information that does not form part of the prior art with respect to the present invention.

### SUMMARY OF THE INVENTION

The present invention has been made in an effort to provide a method for photomask processing having advantages of reducing a process cost by reducing process steps.

An exemplary method for photomask processing according to an embodiment of the present invention includes forming a photoresist pattern for a P-Well, implanting ions for the P-well using the photoresist pattern as an ion implantation mask, coating another photoresist for the N-well that has a higher etch resistance than the photoresist for the P-well, removing the photoresist for the P-well, implanting ions for the N-well, and removing the photoresist.

In a further embodiment, the photoresist for the N-well can have an etch resistance that is at least three times higher than that for the photoresist for the P-well.

Otherwise, in removing the photoresist for the P-well, an etchant having a removing rate that is at least three time higher for the photoresist for the P-well than for the photoresist for the N-well can be used for wet-etching the photoresist.

The photomask processing can also be adopted for forming an N-channel and a P-channel or for forming an N-type source/drain region and a P-type source/drain region.

### BRIEF DESCRIPTION OF THE DRAWINGS

FIG. 1A to FIG. 1B are cross-sectional views showing principal stages of a conventional photomask process.

FIG. 2A is a schematic diagram for showing a P-well mask.

FIG. 2B to FIG. 2G are cross-sectional views showing principal stages of a photomask process according to an exemplary embodiment of the present invention.

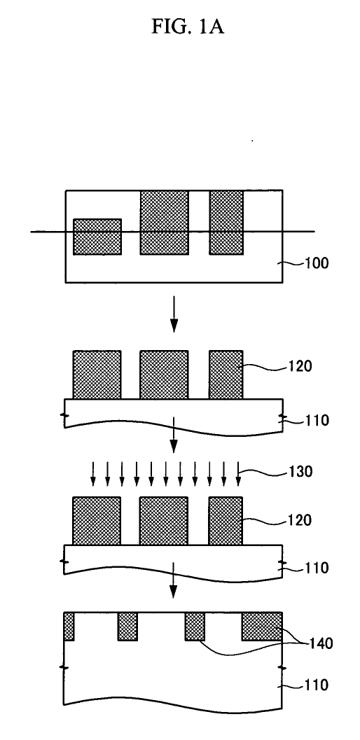

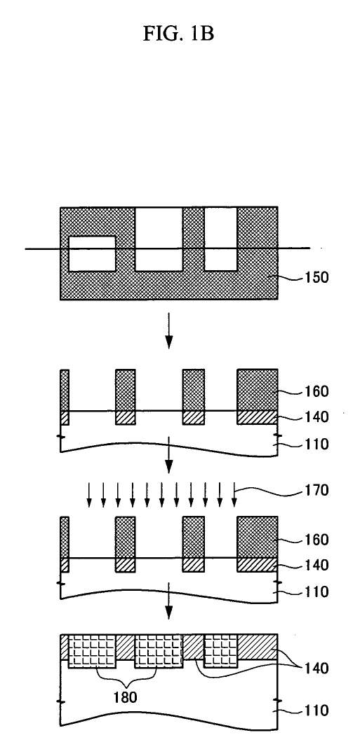

### DETAILED DESCRIPTION OF THE EMBODIMENTS

An exemplary embodiment of the present invention will hereinafter be described in detail with reference to the accompanying drawings.

To clarify multiple layers and regions, the thicknesses of the layers are enlarged in the drawings. Like reference numerals designate like elements throughout the specification. When it is said that any part, such as a layer, film, area, or plate is positioned on another part, it means the part is directly on the other part or above the other part with at least one intermediate part. On the other hand, if any part is said to be positioned directly on another part it means that there is no intermediate part between the two parts.

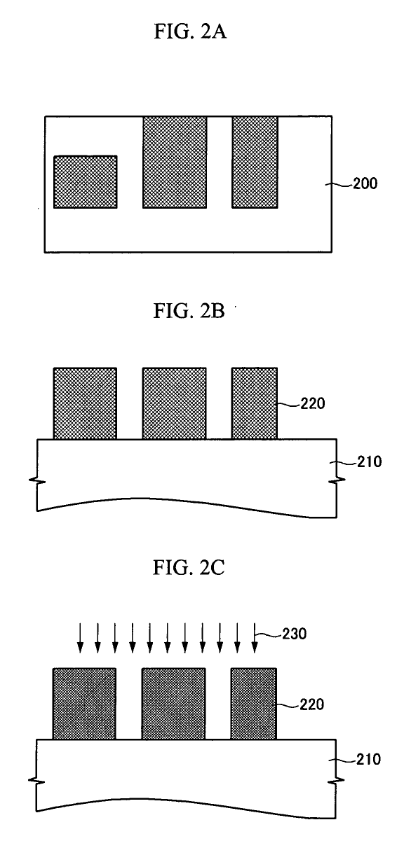

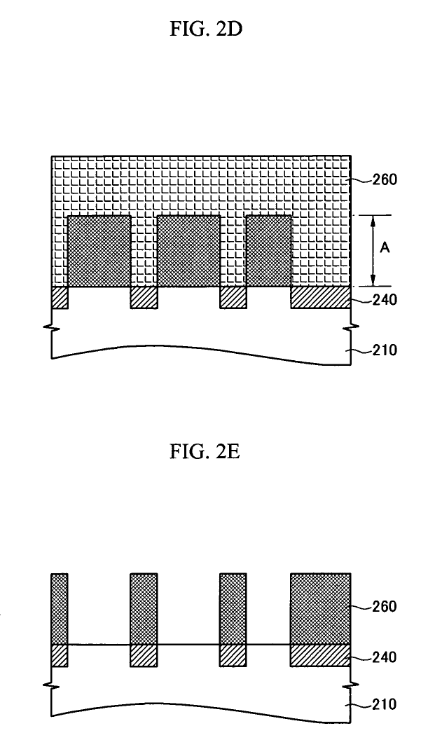

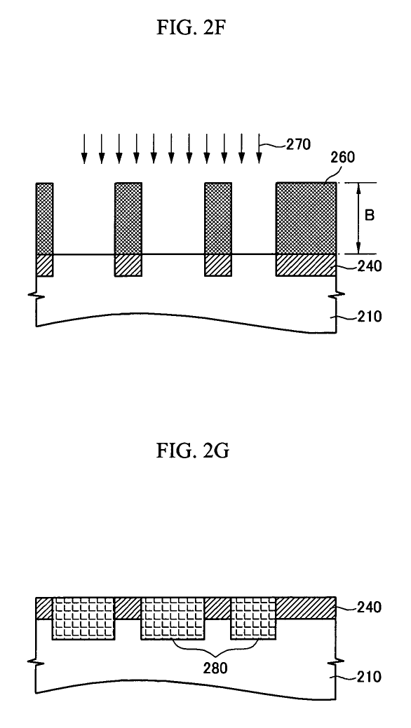

FIG. 2A is a schematic diagram for showing a P-well mask.

FIG. 2B to FIG. 2G are cross-sectional views showing principal stages of a photomask process according to an exemplary embodiment of the present invention.

As shown in FIG. 2B to FIG. 2C, a photoresist is coated on a semiconductor substrate 210. In a P-well photomask process, the photoresist is exposed by using a P-Well photomask 200 and is developed to a predetermined pattern 220. Subsequently, an ion implantation process 230 is performed. Even after the ion implantation process, the photoresist pattern 220 is not removed.

Next, as shown in FIG. 2D, another photoresist 260 for the N-well that has a higher etch resistance than the photoresist for the P-well is coated on the substrate 210 provided with P-wells 240.

Subsequently, as shown in FIG. 2E, the photoresist 220 that was used for forming the P-wells is removed.

After the photoresist 220 for forming the P-wells is removed, the photoresist 260 can remain at a predetermined thickness depending on etch resistance selectivity with the photoresist 220. Therefore, the remaining photoresist 260 can be used as an implantation mask for an N-well ion implantation process. For example, if the selectivity of the P-well photoresist to the N-well photoresist is 4:1, the thickness B in the drawing becomes 0.75 times multiples of A.

Therefore, it is preferable for the photoresist 260 for forming the N-well to have an etch resistance that is at least three times higher than that of the photoresist 220 for forming the P-well. Otherwise, in removing the photoresist for the P-well, an etchant having a removing rate that is at least three times higher for the photoresist for the P-well than that for the photoresist for the N-well can be used for wet-etching the photoresist.

Subsequently, as shown in FIG. 2F, an N-well ion implantation process 270 is performed.

Consequently, as shown in FIG. 2G, after the photoresist 260 that was used for forming the N-wells is removed, the P-wells 240 and the N-wells 280 are formed on the semiconductor substrate 210.

In addition, the photomask processing can also be adopted for forming an N-channel and a P-channel or for forming an N-type source/drain region and a P-type source/drain region.

In the exemplary embodiment according to the present invention, the number of photomask processes for ion implantation can be reduced, so the total processing cost can be reduced. In addition, as the number of photomasks can be reduced, the cost for photomasks can be reduced.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for photomask processing, comprising:
forming a photoresist pattern for a P-Well;
implanting ions for the P-well using the photoresist pattern as an ion implantation mask;
coating another photoresist for the N-well that has a higher etch resistance than that of the photoresist for the P-well;
removing the photoresist for the P-well;
implanting ions for the N-well; and
removing the photoresist.

2. The method of claim 1, wherein the photoresist for the N-well has an etch resistance that is at least three times higher than the photoresist for the P-well.

3. The method of claim 1, wherein, in removing the photoresist for the P-well, an etchant having a removing rate that is at least three times higher for the photoresist for the P-well than for the photoresist for the N-well is used for wet-etching the photoresist.

4. The method of claim 1, wherein the photomask processing is also adopted for forming an N channel and a P channel.

5. The method of claim 1, wherein the photomask processing is also adopted for forming an N-type source/drain region and a P-type source/drain region.
